(19) United States
(12) Patent Application Publication
(10) Pub. No.: US 2022/0212447 A1
(43) Pub. Date: Jul. 7, 2022

(54) COVER PLATE, DISPLAY DEVICE AND METHOD FOR PREPARING COVER PLATE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Fuzheng XIE, Beijing (CN); Xiaoxia Liu, Beijing (CN)

(21) Appl. No.: 17/705,070

(22) Filed: Mar. 25, 2022

Related U.S. Application Data
(63) Continuation of application No. 16/646,835, filed on Mar. 12, 2020.

(30) Foreign Application Priority Data
Nov. 22, 2018 (CN) 201811397315.9

(51) Int. Cl. B32B 17/06; B32B 7/12; G09F 9/30

(52) U.S. Cl. CPC B32B 17/06; B32B 7/12; B32B 2457/206; B32B 2307/546; B32B 2315/08; G09F 9/301

(57) ABSTRACT

The present disclosure relates to a cover plate, a display device and a method for preparing a cover plate. The cover plate of the present disclosure includes a plurality of non-bendable portions and at least one bendable portion, in which every two non-bendable portions are connected by one bendable portion; and the cover plate includes a first end and a second end arranged opposite to each other, and the plurality of non-bendable portions includes a first non-bendable portion located at the first end and a second non-bendable portion located at the second end, the first non-bendable portion including a first curved surface structure, and the second non-bendable portion including a second curved surface structure.

### CROSS-REFERENCE TO RELATED APPLICATION

This application is a continuation of U.S. application Ser. No. 16/646,835 filed on Mar. 12, 2020, which is the U.S. national phase of PCT Application No. PCT/CN2019/107724 filed on Sep. 25, 2019, which claims a priority to Chinese Patent Application No. 201811397315.9 filed on Nov. 22, 2018, the disclosures of which are incorporated in their entirety by reference herein.

### TECHNICAL FIELD

The present disclosure relates to the technical field of producing a display product, and in particular, to a cover plate, a display device, and a method for preparing the cover plate.

### BACKGROUND

In the research of display screens, the development of foldable products is in an initial stage. Flexible organic light-emitting diode (OLED) screens can be bent and attached to ensure the realization of foldable products.

### SUMMARY

The present disclosure provides the following technical solutions.

An embodiment of the present disclosure provides a cover plate, including a plurality of non-bendable portions and at least one bendable portion, in which every two adjacent non-bendable portions are connected by one bendable portion; and the cover plate includes a first end and a second end arranged opposite to each other, the plurality of non-bendable portions includes a first non-bendable portion located at the first end and a second non-bendable portion located at the second end, the first non-bendable portion including a first curved surface structure, and the second non-bendable portion including a second curved surface structure.

In one embodiment, the first curved surface structure is located at an end of the first non-bendable portion away from the second end, and the second curved surface structure is located at an end of the second non-bendable portion away from the first end.

In one embodiment, the cover plate includes a first surface and a second surface arranged opposite to each other, and the first curved surface structure and the second curved surface structure are both curved surface structures bent toward the first surface.

In one embodiment, when the bendable portion is in a folded state, the bendable portion moves close to the first non-bendable portion to form a curved structure having the same curvature as the first curved surface structure.

In one embodiment, the cover plate includes one bendable portion, the first non-bendable portion further includes a first planar structure located between the first curved surface structure and the bendable portion, and the second non-bendable portion further includes a second planar structure located between the second curved surface structure and the bendable portion.

In one embodiment, the cover plate includes at least two bendable portions, the at least two bendable portions includes a first bendable portion connected to the first non-bendable portion and a second bendable portion connected to the second non-bendable portion; and the plurality of non-bendable portions further includes at least one third non-bendable portion located between the first bendable portion and the second bendable portion, in which the third non-bendable portion is of a planar structure.

In one embodiment, a thickness of the plurality of non-bendable portions is greater than or equal to a thickness of the bendable portion.

In one embodiment, the bendable portion includes at least one flexible thin film made of a flexible transparent material along a thickness direction of the bendable portion.

In one embodiment, the bendable portion is made of flexible glass, and the non-bendable portion is made of rigid glass.

An embodiment of the present disclosure further provides a display device including a flexible display panel and the cover plate described above.

In one embodiment, the flexible display panel is connected to the cover plate through attaching, and a portion of the flexible display panel attached to the first curved surface structure and the second curved surface structure is in a curved state.

In one embodiment, the above display device further includes an optical adhesive layer, the optical adhesive layer is located between the flexible display panel and the cover plate for connecting the flexible display panel and the cover plate together, a surface of the cover plate away from the flexible display panel is a planar surface, a thickness of the bendable portion is less than the thickness of the non-bendable portion, so that when the cover plate is attached to the flexible display panel, a gap is formed between the bendable portion and the flexible display panel, and the optical adhesive layer has a filling portion capable of filling the gap at a position corresponding to the bendable portion.

In one embodiment, the above display device further includes an optical adhesive layer, the optical adhesive layer is located between the flexible display panel and the cover plate for connecting the flexible display panel and the cover plate together, a thickness of the bendable portion is equal to a thickness of the non-bendable portion, and a surface of the optical adhesive layer away from the flexible display panel is a planar surface.

In one embodiment, the flexible display panel includes a bending region connected to a main circuit board of the display device, and the display device further includes a spacer located on the surface of the bending region away from the cover plate.

An embodiment of the present disclosure further provides a method for preparing a cover plate, including: forming a plurality of non-bendable portions and at least one bendable portion; and connecting a first connection region of the plurality of non-bendable portions, which is configured to connect a corresponding bendable portion, and a second connection region of the at least one bendable portion, which is configured to connect a corresponding non-bendable portion, to form the cover plate described above.

In one embodiment, the method specifically includes: forming the non-bendable portion in a molten state and the bendable portion in a molten state; and blending the first connection region and the corresponding second connection region, and then curing the first connection region and the corresponding second connection region.

In one embodiment, the step of connecting the first connection region of the plurality of the non-bendable portions, which is configured to connect the corresponding foldable portion, and the second connection region of the at least one bendable portion, which is configured to connect the corresponding non-bendable portion, to form the above cover plate specifically includes: heating and melting the first connection region and the second connection region, to connect the plurality of non-bendable portions and the corresponding bendable portion; and curing the first connection region and the second connection region after blending them.

In one embodiment, the step of connecting the first connection region of the plurality of the non-bendable portions, which is configured to connect the corresponding foldable portion and the second connection region of the at least one bendable portion, which is configured to connect the corresponding non-bendable portion, to form the above cover plate specifically includes: bonding the first connection region and the corresponding second connection region by an optical adhesive.

### BRIEF DESCRIPTION OF THE DRAWINGS

FIG. 1 is a schematic view I showing a structure of a cover plate according to an embodiment of the present disclosure;

FIG. 2 is a schematic view II showing a structure of a cover plate according to another embodiment of the present disclosure;

FIG. 3 is a schematic view III showing a structure of a cover plate according to still another embodiment of the present disclosure;

FIG. 4 is a schematic view IV showing a structure of a cover plate according to still another embodiment of the present disclosure;

FIG. 5 is a schematic view V showing a structure of a display device according to an embodiment of the present disclosure; and

FIG. 6 is a schematic view VI showing a structure of a display device according to another embodiment of the present disclosure.

### DETAILED DESCRIPTION

In order to illustrate the purposes, technical solution and advantages in the embodiments of the present disclosure in a clearer manner, the technical solutions in the embodiments of the present disclosure will be described hereinafter in conjunction with the drawings in a clear and complete manner. Obviously, the following embodiments relate to a part of, rather than all of, the embodiments of the present disclosure. Based on the described embodiments of the present disclosure, a person skilled in the art may obtain the other embodiments, which also fall within the scope of the present disclosure.

In related art, the foldable products have the following problems after bending: the folded position is a folded curved surface screen, and both sides thereof without bending are flat, therefore this asymmetrical display state brings a very bad experience to the user.

An object of the present disclosure is to provide a cover plate, a display device, and a method for preparing a cover plate, which solve the problem of an asymmetric display state of the screen when being in a folded state.

<Cover Plate>

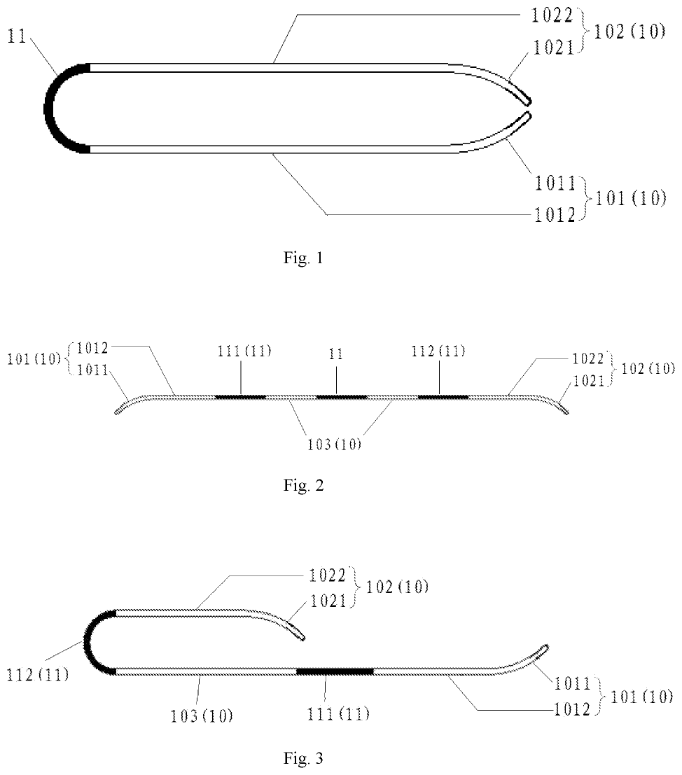

As shown in FIGS. 1 to 4, an embodiment of the present disclosure provides a cover plate 1. The cover plate 1 includes a plurality of rigid non-bendable portions 10 and at least one flexible bendable portion 11. Every two adjacent non-bendable portions 10 are connected by one bendable portion 11. The cover plate 1 includes a first end and a second end arranged opposite to each other. The plurality of non-bendable portions 10 includes a first non-bendable portion 101 located at the first end and a second non-bendable portion 102 located at the second end. The first non-bendable portion 101 comprises a first curved surface structure 1011, and the second non-bendable portion 102 comprises a second curved surface structure 1021.

For the cover plate 1 of this embodiment, a rigid non-bendable portion 10 and a flexible bendable portion 11 are combined. The cover plate 1 includes a first end and a second end arranged opposite to each other, the first non-bendable portion 101 located at the first end includes a first curved surface structure 1011, and the second non-bendable portion 102 located at the second end includes a second curved surface structure 1021. When the cover plate 1 is in an unfolded state or in a folded state, a display effect that both sides opposite to each other may be formed into a curved surface, thereby improving the user experience.

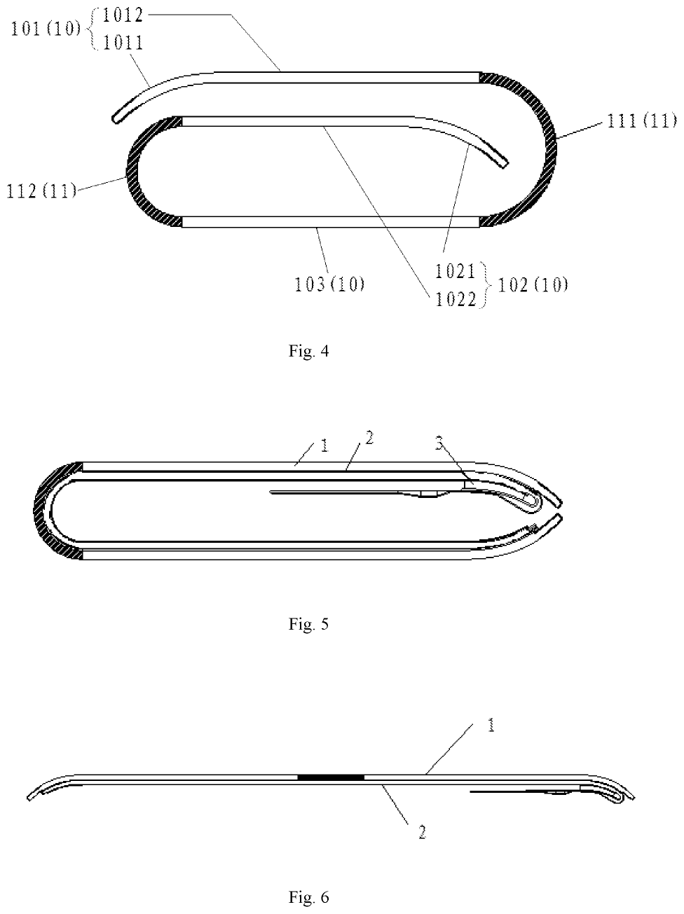

The number of the bendable portions 11 can be set according to actual needs, and is not particularly limited. For example, in this embodiment, the bendable portion 11 may be one, or two or more. For example, FIG. 1 shows a schematic view of the structure of a cover plate 1 having one bendable portion 11, FIG. 2 shows a schematic view of the structure of a cover plate 1 having three bendable portions 11, and FIGS. 3 and 4 show a schematic view of the structure of a cover plate 1 having two bendable portions 11. When the cover plate 1 is in an unfolded state, that is, when a full screen is displayed, a display effect that both sides are curved surfaces can be achieved by setting the first curved surface structure 1011 and the second curved surface structure 1021. When any one of the bendable portions 11 is displayed in a folded state, a display effect that both sides are curved surfaces is also achieved. For example, FIG. 1 is a schematic view showing a folded state of a cover plate 1 having a bendable portion 11. As shown in FIG. 1, when the cover plate 1 is in a folded state, the first curved surface structure 1011 and the second curved surface structure 1021 cooperate with the curved surface at the bending position, so that a display effect that both sides of the cover plate 1 are curved surfaces is achieved along the first direction (X direction). FIGS. 3 and 4 show a schematic view showing the folded states at different bending positions when there are the two bending portions 11. As shown in FIGS. 3 and 4, regardless how the bend is made, and regardless in which bendable portion 11 the bend position is located, a display effect that both sides are curved surfaces can be achieved, thereby improving the user experience.

The cover plate 1 of this embodiment is capable of realizing the adjustability of the size of the display region and the adjustability of the display position by providing one or two or more bendable portions 11. For example, the cover plate 1 having one bendable portion 11 shown in FIG. 1 is folded in a center folded state at the bendable portion 11, thereby realizing ½ area display. The cover plate 1 shown in FIG. 2 is in an unfolded state, that is, a full screen is displayed. At this time, a display effect that both sides of the cover plate 1 in an unfolded state are still curved surfaces can be achieved by setting the first curved surface structure 1011 and the second curved surface structure 1021. The folded state of the cover plate 1 shown in FIG. 3 can realize ⅓ area display or ⅔ area display. The folded state of the cover plate 1 shown in FIG. 4 can realize ⅓ area display. In actual use, the size of the display region can be freely adjusted according to the setting of the position of the bendable portion 11, and the area of the display module can be adjusted by bending the bendable portion 11 at different positions, so that it is convenient to carry.

In this embodiment, the first curved surface structure 1011 is located at an end of the first non-bendable portion 101 away from the second end, and the second curved surface structure 1021 is located at an end of the second non-bendable portion 102 away from the first end.

In this embodiment, the cover plate 1 includes a first surface for connecting the flexible display panel 2 (as shown in FIG. 6) and a second surface arranged opposite to the first surface. The first curved surface structure 1011 and the second curved surface structure 1021 are both curved surface structures bent toward the first surface.

The first curved surface structure 1011 and the second curved surface structure 1021 have the same bending direction, thereby being capable of improving the display effect.

Typically, when the cover plate 1 is in a unfolded state, the first curved surface structure 1011 and the second curved surface structure 1021 have the same curvature, so that a symmetrical display effect is achieved on opposite sides of the cover plate 1, thereby being capable of improving the user experience.

In this embodiment, when the bendable portion 11 is in a folded state, a portion of the bendable portion 11 moves close to the first non-bendable portion 101 to form a curved structure having the same curvature as the first curved surface structure 1011, or to form a curved structure having a curvature different from the first curved surface structure 1011. Typically, a portion of the bendable portion 11 moves close to the first non-bendable portion 101 to form a curved structure having the same curvature as the first curved surface structure 1011. It should be noted that, in the schematic view of the folded state of the cover plate 1 having a bendable portion 11 shown in FIG. 1, the portion of the bendable portion 11 proximate to the first non-bendable portion 101 has a curvature different from the first curved surface structure 1011, but it is not a limitation on the protection range of the cover plate 1 of the present disclosure.

In one embodiment, as shown in FIG. 1, the cover plate 1 includes a bendable portion 11, the first non-bendable portion 101 further includes a first planar structure 1012 located between the first curved surface structure 1011 and the bendable portion 11, and the second non-bendable portion 102 further includes a second planar structure 1022 located between the second curved surface structure 1021 and the bendable portion 11.

In the folded state, the first planar structure is a planar display region, and both sides of the first planar structure are curved surface display regions. Similarly, the second planar structure is a planar display region, and both sides of the second planar structure are curved surface display regions, thereby being capable of improving the display effect.

In another embodiment, the cover plate 1 includes at least two bendable portions 11. At this time, there may be various specific structures of the cover plate 1. Exemplarily, as shown in FIGS. 2 to 4, there are at least two bendable portions 11, and the at least two bendable portions 11 include a first bendable portion 111 connected to the first non-bendable portion 101 and a second bendable portion 112 connected to the second non-bendable portion 102. The non-bendable portion 10 further includes at least one third non-bendable portion 103 located between the first bendable portion 111 and the second bendable portion 112. The third non-bendable portion 103 is of a planar structure.

In this embodiment, the thickness of the non-bendable portion 10 is greater than or equal to the thickness of the bendable portion 11. Thus, the bendability of the bendable portion 11 is ensured.

There may be various specific structural forms of the bendable portion 11. For example, in this embodiment, the bendable portion 11 includes at least one flexible thin film made of a flexible transparent material along its thickness direction. Exemplarily, the bendable portion 11 is made of flexible glass, and the non-bendable portion 10 is made of rigid glass.

<Display Device>

As shown in FIGS. 5 and 6, an embodiment of the present disclosure further provides a display device including a flexible display panel 2 and the above cover plate 1. The combination of the flexible display panel 2 and the above cover plate 1 can realize the display effect that the two opposite sides of the display module are curved surfaces, thereby improving the user experience.

There are various manners of connecting the flexible display panel 2 and the cover plate 1. For example, in this embodiment, the flexible display panel 2 is connected to the cover plate 1 through attaching, and a portion of the flexible display panel 2 attached to the first curved surface structure 1011 and the second curved surface structure 1021 is in a curved state.

Exemplarily, the flexible display panel 2 and the cover plate 1 may be attached by an optical adhesive layer (not shown in the figure). Since the display surface of the flexible display panel 2 is generally a planar surface, the surface of the optical adhesive layer connected to the flexible display panel 2 is a planar surface in order to avoid affecting the display effect. The surface of the optical adhesive layer connected to the cover plate 1 is used to match the structure of the surface of the cover plate 1 connected to the optical adhesive layer.

In one embodiment, an optical adhesive layer is provided between the flexible display panel 2 and the cover plate 1. The surface of the cover plate 1 away from the flexible display panel 2 is a planar surface. The thickness of the bendable portion 11 is smaller than the thickness of the non-bendable portion 10, so that when the cover plate 1 is attached to the flexible display panel 2, a gap is formed between the bendable portion 11 and the display panel 2, and the optical adhesive layer has a filling portion capable of filling the gap at a position corresponding to the bendable portion. For example, the thickness of the non-bendable portion 10 may be 0.5 mm, and the thickness of the bendable portion 11 may be 0.1 mm, but is not limited thereto.

When the attaching process of the flexible display panel 2 and the cover plate 1 is performed, an optical adhesive layer may be provided on the cover plate 1 to form a filling portion, and then an optical adhesive layer may be provided to connect the flexible display panel 2 and the cover plate 1.

In another embodiment, an optical adhesive layer is provided between the flexible display panel 2 and the cover plate 1. The thickness of the bendable portion 11 is equal to the thickness of the non-bendable portion 10, and the surface of the optical adhesive layer away from the flexible display panel 2 is a planar surface.

In this embodiment, in order to ensure the bending performance of the bendable portion 11, the bendable portion 11 may include several layer of flexible thin film. For example, the bendable portion 11 includes 5 layers of flexible thin films made of flexible glass. Each layer of the flexible thin film has a thickness of 0.1 mm, and the thickness of the non-bendable portion 10 is 0.5 mm, but is not limited thereto.

In this embodiment, as shown in FIG. 5, the flexible display panel 2 includes a bending region connected to a main circuit board (not shown in the figure) of the display device, and the display device further includes a spacer 3 located on a surface of the bending region away from the cover plate 1. Providing the spacer 3 is capable of preventing the flexible display panel 2 from being bent excessively, and reducing the risk of damage to the flexible display panel 2 during the bending process.

The display device of the embodiments may include any product or component having a display function, such as a liquid crystal television, a liquid crystal display, a digital photo frame, a mobile phone, and a tablet computer. Further, the display device may further include a flexible circuit board, a printed circuit board, and a backplane. It has application value in the fields of augmented reality (AR)/virtual reality (VR) and other fields in the future.

<Method for Preparing a Cover Plate>

There are many methods for preparing a cover plate. An embodiment of the present disclosure provides a method for preparing a cover plate, which is applied to the above cover plate and includes: forming a plurality of non-bendable portions and at least one bendable portion; and connecting a first connection region of the plurality of the non-bendable portions, which is configured to connect a corresponding foldable portion, and a second connection region of the at least one bendable portion, which is configured to connect a corresponding non-bendable portion, to form the above cover plate.

There are various manner of connecting the bendable portion and the non-bendable portion. For example, the connection can be made by melting or by bonding. Several connection manner of the embodiments will be described hereafter.

In one embodiment, the method for preparing the cover plate specifically includes: forming a rigid non-bendable portion in a molten state and a flexible bendable portion in a molten state; and blending the first connection region and the corresponding second connection region, and then curing the first connection region and the corresponding second connection region.

Hereafter, a cover plate having a bendable portion is taken as an example to explain the preparing process of the cover plate in detail. Ordinary rigid glass (such as GG3 glass) is put into two molds, to make the rigid glass be in a molten state and be ready for use (i.e., forming the first non-bendable portion and the second non-bendable portion in the molten state). Then, one mold containing flexible glass is added between the two molds, to make the flexible glass be in a molten state and be ready for use (i.e., forming a bendable portion). Then, the three molds are connected, the temperature is well controlled, the joints of the three molds are opened, and the temperature is gradually reduced to achieve the connection between the rigid glass and the flexible glass in the three molds. Then a cover plate is formed after curing.

The first curved surface structure on the first non-bendable portion and the second curved surface structure on the second non-bendable portion can be directly formed by using a mold of the corresponding structure, or can be formed by processing after curing. The processing method may be, for example, shown as follows. After curing the rigid glass and flexible glass in three molds, the surfaces of the connected rigid glass and flexible glass are polished and flattened by grinding and CNC cutting (heterosexual cutting), and then the edges of the rigid glass are hot-bent to form a first curved surface structure on the first non-bendable portion and a second curved surface structure on the second non-bendable portion, thereby achieving a final mass production.

In one embodiment, the step of connecting the first connection region of the plurality of the non-bendable portions, which is configured to connect the corresponding foldable portion, and the second connection region of the at least one bendable portion, which is configured to connect the corresponding non-bendable portion, to form the above cover plate specifically includes: heating and melting the first connection region and the second connection region, to connect the plurality of non-bendable portions and the corresponding bendable portion; and curing the first connection region and the second connection region after blending them.

Specifically, the rigid glass material and the flexible glass material are put into corresponding planar molds, respectively, and then both of them are pre-baked, and attached when cured to a certain degree. Then, the respective melting temperatures of the rigid glass material and the flexible glass material are adjusted to fuse the joints between them. After the fusion, the temperature is gradually reduced. After the curing, the treatment of the binding parts of them is completed by grinding, CNC cutting (heterosexual cutting) and other treatments. Then, the edge of the rigid glass is hot-bent to form a first curved surface structure and a second curved surface structure.

In this embodiment, the first curved surface structure and the second curved surface structure may also be formed in a mold of the corresponding structure directly through processes such as melting and curing.

In this embodiment, the material of the rigid non-bendable portion may be CG material (composite material), and the material of the flexible bendable portion may be CG material (composite material) or flexible PET (polyethylene terephthalate) material, etc.

In one embodiment, the step of connecting the first connection region of the plurality of the non-bendable portions, which is configured to connect the corresponding foldable portion, and the second connection region of the at least one bendable portion, which is configured to connect the corresponding non-bendable portion, to form the above cover plate specifically includes: bonding the first connection region and the corresponding second connection region by an optical adhesive.

The above descriptions are optional embodiments of the present disclosure. It should be noted that one skilled in the art would make several improvements and substitutions without departing from the principles of the present disclosure. These improvements and modifications should also be regarded as the protection scope of the present disclosure.

What is claimed is:

1. A display device, comprising a flexible display panel and a cover plate,
wherein the cover plate, comprising a plurality of non-bendable portions and at least one bendable portion,
wherein every two adjacent non-bendable portions are connected by one bendable portion,
wherein the cover plate comprises a first end and a second end arranged opposite to each other, the plurality of non-bendable portions comprises a first non-bendable portion located at the first end and a second non-bendable portion located at the second end, the first non-bendable portion comprises a first curved surface structure, and the second non-bendable portion comprises a second curved surface structure; and
wherein the flexible display panel is connected to the cover plate through attaching, and a portion of the flexible display panel attached to the first curved surface structure and the second curved surface structure is in a curved state.

2. The display device of claim 1, wherein the first curved surface structure is located at a part of the first non-bendable portion away from the second end, and the second curved surface structure is located at a part of the second non-bendable portion away from the first end.

3. The display device of claim 1, wherein the cover plate comprises a first surface and a second surface arranged opposite to each other, and the first curved surface structure and the second curved surface structure are both curved surface structures bent toward the first surface.

4. The display device of claim 1, wherein when the bendable portion is in a folded state, a part of the bendable portion proximate to the first non-bendable portion is a curved structure having a same curvature as the first curved surface structure.

5. The display device of claim 1, wherein the cover plate comprises one bendable portion, the first non-bendable portion further comprises a first planar structure located between the first curved surface structure and the bendable portion, and the second non-bendable portion further comprises a second planar structure located between the second curved surface structure and the bendable portion.

6. The display device of claim 1, wherein the cover plate comprises at least two bendable portions, the at least two bendable portions comprises a first bendable portion connected to the first non-bendable portion and a second bendable portion connected to the second non-bendable portion; and
the plurality of non-bendable portions further comprises at least one third non-bendable portion located between the first bendable portion and the second bendable portion, wherein the third non-bendable portion is of a planar structure.

7. The display device of claim 1, wherein a thickness of the plurality of non-bendable portions is greater than or equal to a thickness of the bendable portion.

8. The display device of claim 1, wherein the bendable portion comprises at least one flexible thin film made of a flexible transparent material along a thickness direction of the bendable portion.

9. The display device of claim 1, wherein the bendable portion is made of flexible glass, and the non-bendable portion is made of rigid glass.

10. The display device of claim 1, wherein the display device further comprises an optical adhesive layer, the optical adhesive layer is located between the flexible display panel and the cover plate for connecting the flexible display panel and the cover plate together,
a surface of the cover plate away from the flexible display panel is a planar surface,
a thickness of the bendable portion is less than the thickness of the non-bendable portion so that when the cover plate is attached to the flexible display panel, a gap is formed between the bendable portion and the flexible display panel, and
the optical adhesive layer has a filling portion capable of filling the gap at a position corresponding to the bendable portion.

11. The display device of claim 1, wherein the display device further comprises an optical adhesive layer, the optical adhesive layer is located between the flexible display panel and the cover plate for connecting the flexible display panel and the cover plate together,
a thickness of the bendable portion is equal to a thickness of the non-bendable portion, and
a surface of the optical adhesive layer away from the flexible display panel is a planar surface.

12. The display device of claim 1, wherein the flexible display panel comprises a bending region connected to a main circuit board of the display device, and the display device further comprises a spacer located on a surface of the bending region away from the cover plate.
